(19) United States
(12) Patent Application Publication
(10) Pub. No.: US 2012/0288795 A1
(43) Pub. Date: Nov. 15, 2012

(54) COMPOSITION FOR FORMATION OF PHOTOSENSITIVE RESIST UNDERLAYER FILM AND METHOD FOR FORMATION OF RESIST PATTERN

(75) Inventors: Makiko Umezaki, Toyama-shi (JP); Takahiro Kishioka, Toyama-shi (JP); Yusuke Horiguchi, Toyama-shi (JP); Hirokazu Nishimaki, Toyama-shi (JP); Tomoya Ohashi, Toyama-shi (JP); Yuki Usui, Toyama-shi (JP)

(73) Assignee: NISSAN CHEMICAL INDUSTRIES, LTD., TOKYO (JP)

(21) Appl. No.: 13/522,392

(22) PCT Filed: Nov. 16, 2010
(86) PCT No.: PCT/JP2010/070380

§ 371 Date: Jul. 16, 2012

(30) Foreign Application Priority Data
Jan. 18, 2010 (JP) 2010-008361

(51) Int. Cl. G03F 7/027; G03F 7/20

(52) U.S. Cl. 430/271.1; 430/319

(57) ABSTRACT

A composition for forming a photosensitive resist underlayer film and a method for forming a resist pattern. The composition for forming a photosensitive resist underlayer film includes a polymer having a structural unit of Formula (1), a compound having at least two vinyl ether groups, a photo-acid generator; and a solvent:

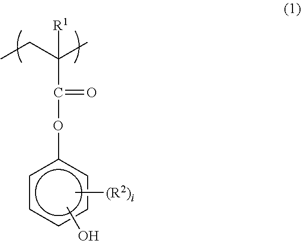

where R¹ is a hydrogen atom or a methyl group, R² is a C₁₋₄ alkyl group, and i is an integer of 0 to 4.

### TECHNICAL FIELD

The present invention relates to a composition for forming a photosensitive resist underlayer film and a method for forming a resist pattern using a resist underlayer film formed from the composition and more specifically relates to the composition capable of forming a resist underlayer film that enables patterning of the resist underlayer film following a resist pattern and a method for forming a resist pattern using a resist underlayer film formed from the composition.

### BACKGROUND ART

Conventionally, microfabrication has been carried out through lithography using a photoresist composition in the production of semiconductor devices. The microfabrication is a machining process in which a thin film of a photoresist composition is formed on a silicon wafer, active light such as ultraviolet light is applied onto the film through a mask pattern with a pattern of a semiconductor device followed by development, and the silicon wafer is etched using the obtained resist pattern as a protective film.

Therefore, various compositions for forming a resist underlayer film for lithography have been developed in the related art.

Meanwhile, various materials including a polymer having, as a structural unit, hydroxyphenyl(meth)acrylate or a derivative thereof have been disclosed until now. For example, disclosed are a photoresist characterized by including a polymer having hydroxyphenyl(meth)acrylate or a derivative thereof (Patent Document 1), a photosensitive resin composition for an interlayer insulation film characterized by including an alkali soluble resin component (A) and a photosensitizing agent (B), the component (A) including a resin component (A1) having, as a structural unit (a1), hydroxyphenyl(meth)acrylate or a derivative thereof (Patent Document 2), a photosensitive resin composition characterized by including a resin component (A1) having a structural unit (a1′) that is obtained by substituting at least a part of hydrogen atoms of phenolic hydroxy groups with a naphthoquinone-1,2-diazide-5-(and/or -4-) sulfonyl group in hydroxyphenyl(meth)acrylate or a derivative thereof (a1) as a structural unit (Patent Document 3), a photosensitive resin composition characterized by including a polymer [A] containing, as a polymer component, hydroxyphenyl (meth)acrylate, a quinonediazide group-containing compound [B], and a thermosetting resin [C] (Patent Document 4), and a photoresist composition including a photoactive component and a resin, the resin having i) one or more spaced phenolic groups and ii) one or more photoacid-labile groups (Patent Document 5).

In the present specification, hydroxyphenyl methacrylate and hydroxyphenyl acrylate are generically called hydroxyphenyl(meth)acrylate.

However, it is simply described that the photosensitive resin composition described in Patent Document 3 is suited for fanning a pattern constituting a color filter and that the photosensitive resin composition described in Patent Document 4 is suited for an interlayer insulation film of an electronic component and for a microlens of a solid-state image sensing device. In other words, these literatures do not intend the application of the polymer containing, as a structural unit, hydroxyphenyl(meth)acrylate or a derivative thereof to a composition for forming a photosensitive resist underlayer film. In addition, the literatures suggest no specific means and effect of a composition for forming a photosensitive resist underlayer film including the polymer containing, as a structural unit, hydroxyphenyl(meth)acrylate or a derivative thereof, a compound having at least two vinyl ether groups, a photo-acid generator, and a solvent.

### RELATED ART DOCUMENTS

### Patent Documents

Patent Document 1: Japanese Patent Application Publication No. JP-A-2006-111802
Patent Document 2: Japanese Patent Application Publication No. JP-A-2006-259083
Patent Document 3: Japanese Patent Application Publication No. JP-A-2006-259461
Patent Document 4: Japanese Patent Application Publication No. JP-A-2007-033517
Patent Document 5: Japanese Patent Application Publication No. JP-A-2008-287223

### SUMMARY OF THE INVENTION

### Problem to be Solved by the Invention

In view of the above circumstances, it is an object of the present invention to provide a composition for forming a photosensitive resist underlayer film including a polymer containing, as a structural unit, hydroxyphenyl(meth)acrylate or a derivative thereof and a method for forming a resist pattern using a resist underlayer film formed from the composition.

### Means for Solving the Problem

The inventors of the present invention have carried out intensive studies in order to solve the problems and, as a result, have found the present invention.

That is, as a first aspect, a composition for forming a photosensitive resist underlayer film includes a polymer having a structural unit of Formula (1), a compound having at least two vinyl ether groups, a photo-acid generator, and a solvent:

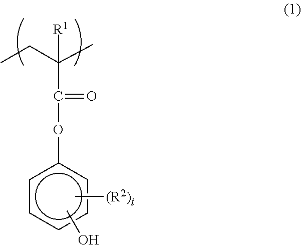

(where R¹ is a hydrogen atom or a methyl group, R² is a C₁₋₄ alkyl group, and i is an integer of 0 to 4).

As a second aspect, a method for forming a photoresist pattern used for producing a semiconductor device. The method includes applying the composition for forming a photosensitive resist underlayer film according to the first aspect onto a semiconductor substrate followed by baking to form a resist underlayer film, forming a photoresist film on the resist underlayer film, exposing the semiconductor substrate covered with the resist underlayer film and the photoresist layer, and developing the semiconductor substrate after the exposure.

### Effects of the Invention

The composition for forming a photosensitive resist underlayer film of the present invention can form a resist underlayer film that enables patterning of the resist underlayer film following a resist pattern.

The composition for forming a photosensitive resist underlayer film of the present invention provides the effect of not causing intermixing of a resist underlayer film formed from the composition with a photoresist on the resist underlayer film.

The composition for forming a photosensitive resist underlayer film of the present invention can provide a resist underlayer film that is well developed using an alkaline developer and can remarkably reduce the generation of a residue.

The composition for forming a photosensitive resist underlayer film of the present invention can provide a resist underlayer film that can remarkably improve shape control.

The composition for forming a photosensitive resist underlayer film of the present invention can form a resist underlayer film having excellent solvent resistance.

The method for forming a photoresist pattern of the present invention enables the formation of a high precision and good photoresist pattern due to the formation of the resist underlayer film having the effects and performance.

### BRIEF DESCRIPTION OF THE DRAWINGS

FIG. 1 shows a cross-sectional view of a photoresist pattern using a composition for forming a photosensitive resist underlayer film of Example 1.

FIG. 2 shows a cross-sectional view of a photoresist pattern using a composition for forming a photosensitive resist underlayer film of Example 2.

FIG. 3 shows a cross-sectional view of a photoresist pattern using a composition for forming a photosensitive resist underlayer film of Example 3.

FIG. 4 shows a cross-sectional view of a photoresist pattern using a composition for forming a photosensitive resist underlayer film of Example 4.

FIG. 5 shows a cross-sectional view of a photoresist pattern using a composition for forming a photosensitive resist underlayer film of Example 5.

FIG. 6 shows a cross-sectional view of a photoresist pattern using a composition for forming a photosensitive resist underlayer film of Comparative Example 1.

FIG. 7 shows a cross-sectional view of a photoresist pattern using a composition for forming a photosensitive resist underlayer film of Comparative Example 3.

FIG. 8 shows a cross-sectional view of a photoresist pattern using a composition for forming a photosensitive resist underlayer film of Comparative Example 4.

FIG. 9 shows a cross-sectional view of a photoresist pattern using a composition for forming a photosensitive resist underlayer film of Comparative Example 5.

FIG. 10 shows a cross-sectional view of a photoresist pattern using a composition for forming a photosensitive resist underlayer film of Comparative Example 6.

FIG. 11 shows a cross-sectional view of a photoresist pattern using a composition for forming a photosensitive resist underlayer film of Comparative Example 7.

FIG. 12 shows a cross-sectional view of a photoresist pattern using a composition for forming a photosensitive resist underlayer film of Comparative Example 8.

### MODES FOR CARRYING OUT THE INVENTION

The composition for forming a photosensitive resist underlayer film of the present invention includes a polymer having a structural unit of Formula (1), a compound having at least two vinyl ether groups, a photo-acid generator, and a solvent. The composition for forming a photosensitive resist underlayer film of the present invention may further include a basic compound, a surfactant, and the like.

The solid content in the composition for forming a photosensitive resist underlayer film is not particularly limited as long as each component is homogeneously dissolved but is, for example, 0.1% to 70% by mass and 1% to 60% by mass. Here, the solid content is a content of all components in the composition for forming a photosensitive resist underlayer film except for a solvent.

Hereinafter, the composition for forming a photosensitive resist underlayer film of the present invention will be described in detail.

The polymer used in the present invention is a polymer having a structural unit of Formula (1):

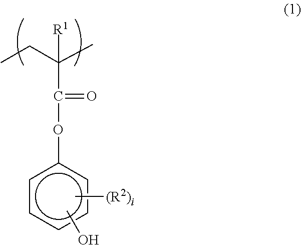

(where R¹ is a hydrogen atom or a methyl group, R² is a C₁₋₄ alkyl group, and i is an integer of 0 to 4).

The polymer may include a structural unit of Formula (2) as a structural unit in addition to the structural unit of Formula (1):

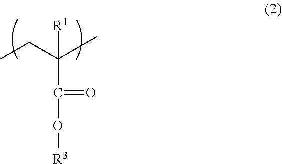

(where R¹ is a hydrogen atom or a methyl group, and R³ is a substituent capable of being deprotected by an acid).

The substituent R³ capable of being deprotected by an acid is a hydrocarbon group in which the carbon atom bonded to the oxygen atom (bonded to the carbonyl group in Formula (2)) is a tertiary carbon atom. The substituent capable of being deprotected by an acid is also called a protective group or an acid-dissociating group.

Examples of R³ include an ethyladamantyl group, an ethylcyclohexyl group, an isopropyladamantyl group, and a tert-butyl group. Specific examples of the structural unit of Formula (2) include structural units of Formula (3) to Formula (9) and two or more types of the structural units of Formula (3) to Formula (9) may be combined:

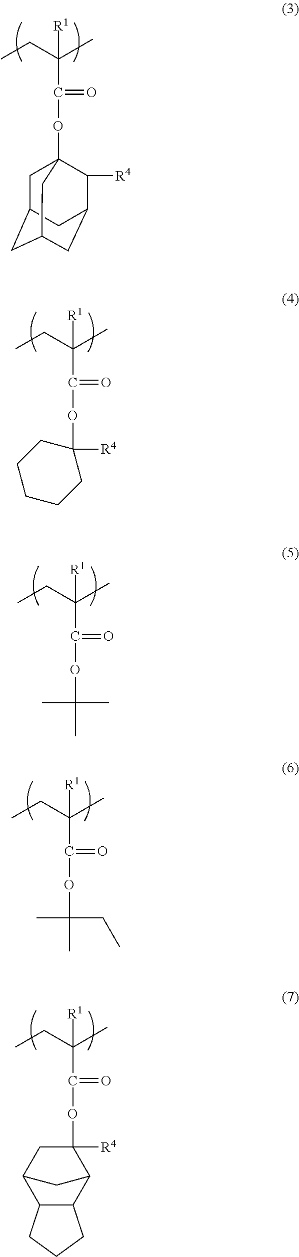

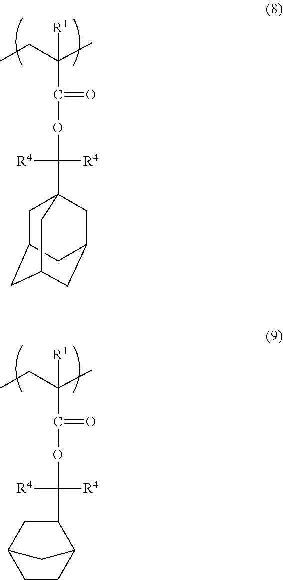

(where R¹ is a hydrogen atom or a methyl group, and R⁴ is a C₁₋₄ alkyl group; and for a plurality of R⁴s, R⁴s may be the same as or different from each other).

The synthetic method of the polymer included in the composition for forming a photosensitive resist underlayer film of the present invention is not particularly limited. For example, the polymer can be synthesized by heat polymerization of a compound of Formula (10) or of the compound and a compound of Formula (11) in an organic solvent with a polymerization initiator.

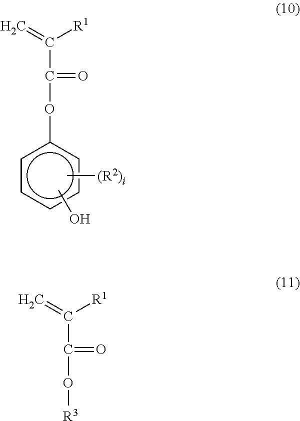

{in Formula (10), R¹, R², and i are the same as the definitions in Formula (1).

In Formula (11), R¹ and R³ are the same as the definitions in Formula (2)}

Examples of the polymerization initiator include 2,2′-azobisisobutyronitrile, 2,2′-azobis(2,4-dimethylvaleronitrile), dimethyl 2,2′-azobis(isobutyrate), dimethyl 2,2′-azobis(2-methyl propionate), benzoyl peroxide, and lauroyl peroxide. Such a polymerization initiator is typically heated at 50° C. to 80° C. to perform polymerization. A typical reaction time is 2 to 100 hours or 5 to 30 hours.

Examples of the polymer having the structural unit of Formula (1) and the structural unit of Formula (2), that is, a copolymer include 4-hydroxyphenyl methacrylate (hereinafter, abbreviated as PQMA in the present specification)/ethyladamantyl methacrylate (hereinafter, abbreviated as EAMA in the present specification), 4-hydroxyphenyl methacrylate (PQMA)/ethylcyclohexyl methacrylate (hereinafter, abbreviated as ECMA in the present specification), 4-hydroxyphenyl methacrylate (PQMA)/isopropyladamantyl methacrylate (hereinafter, abbreviated as IAM in the present specification), and 4-hydroxyphenyl methacrylate (PQMA)/N-(4-hydroxyphenyl)methacrylamide.

When the polymer used in the present invention has the structural unit of Formula (2) in addition to the structural unit of Formula (1), the molar ratio of Formula (1) and Formula (2) is not particularly limited but is, for example, 1:1.

The polymer used in the present invention may include a structural unit (for example, represented by Formula (12)) different from the structural unit of Formula (2), together with the structural unit of Formula (1).

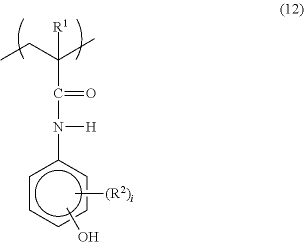

{in Formula (12), R¹, R², and i are the same as the definitions in Formula (1)}

The polymer commonly has a weight average molecular weight of 1,000 to 200,000 or 3,000 to 30,000. A polymer having a weight average molecular weight of less than 3,000 may provide cause of insufficient solvent resistance, while a polymer having an excessively large weight average molecular weight may cause a problem in resolution. The weight average molecular weight is a value obtained by gel permeation chromatography (GPC) using polystyrene as a standard sample.

The composition for forming a photosensitive resist underlayer film of the present invention includes the polymer in an amount of, for example, 0.5% to 95% by mass or 1.0% to 90% by mass based on the solid content in the composition for forming a photosensitive resist underlayer film. This is because a composition including the polymer in an excessively small amount or an excessively large amount may be unlikely to provide solvent resistance.

The compound having at least two vinyl ether groups used in the present invention is a cross-linking agent and is a compound having 2 to 20, preferably 3 to 10, and more preferably 3 to 6 vinyl ether groups.

Examples of the compound having at least two vinyl ether groups include, but are not necessarily limited to, bis(4-(vinyloxymethyl)cyclohexylmethyl)glutarate, tri(ethylene glycol)divinyl ether, divinyl adipate, diethylene glycol divinyl ether, 1,2,4,-tris(4-vinyloxybutyl)trimellitate, 1,3,5,-tris(4-vinyloxybutyl)trimellitate, bis(4-(vinyloxybutyl))terephthalate, bis(4-(vinyloxybutyl))isophthalate, ethylene glycol divinyl ether, 1,4-butanediol divinyl ether, tetramethylene glycol divinyl ether, tetraethylene glycol divinyl ether, neopentyl glycol divinyl ether, trimethylolpropane trivinyl ether, trimethylolethane trivinyl ether, hexanediol divinyl ether, 1,4-cyclohexanediol divinyl ether, tetraethylene glycol divinyl ether, pentaerythritol divinyl ether, pentaerythritol trivinyl ether, and cyclohexanedimethanol divinyl ether. These compounds may be used singly or in combination of two or more of them.

The composition for forming a photosensitive resist underlayer film of the present invention includes the compound having at least two vinyl ether groups in an amount of, for example, 0.1% to 70% by mass or 1% to 60% by mass based on the solid content in the composition for forming a photosensitive resist underlayer film. This is because a composition including the compound in an excessively small amount or an excessively large amount may be unlikely to provide solvent resistance.

The photo-acid generator used in the present invention is not particularly limited as long as the compound generates an acid by photoirradiation used for exposure. Examples of the photo-acid generator include diazomethane compounds, onium salt compounds, sulfonimide compounds, nitrobenzyl compounds, benzoin tosylate compounds, halogen-containing triazine compounds, and cyano group-containing oxime sulfonate compounds. Among them, onium salt compounds are preferred.

Specific examples of the onium salt compounds include iodonium salts such as diphenyliodonium hexafluorophosphate, diphenyliodonium trifluoromethanesulfonate, diphenyliodonium nonafluoro-n-butanesulfonate, diphenyliodonium perfluoro-n-octanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds such as triphenylsulfonium hexafluoroantimonate, triphenylsulfonium nonafluoro-n-butanesulfonate, triphenylsulfonium camphorsulfonate, triphenylsulfonium perfluorobutylsulfonate, and triphenylsulfonium trifluoromethanesulfonate.

Specific examples of the sulfonimide compounds include N-(trifluoromethanesulfonyloxy)succinimide, N-(nonafluoro-n-butanesulfonyloxy)succinimide, N-(camphorsulfonyloxy)succinimide, and N-(trifluoromethanesulfonyloxy)naphthalimide.

The composition for forming a photosensitive resist underlayer film of the present invention includes the photo-acid generator in an amount of, for example, 0.01% to 10% by mass or 0.01% to 5% by mass based on the solid content in the composition for forming a photosensitive resist underlayer film. A composition for forming a resist underlayer film including the photo-acid generator in an amount of more than 10% by mass may have reduced storage stability and consequently may affect the pattern shape of a photoresist.

The composition for forming a photosensitive resist underlayer film of the present invention may further include a basic compound (quencher).

The addition of the basic compound enables sensitivity adjustment of a resist underlayer film at the time of exposure. The basic compound can be reacted with an acid generated from a photo-acid generator at the time of exposure to reduce the sensitivity of a resist underlayer film. The basic compound can also suppress the diffusion of an acid generated from a photo-acid generator in the resist underlayer film in an exposed area to the resist underlayer film in an unexposed area.

Examples of the basic compound include amines and ammonium hydroxides.

Examples of the amines include, but are not necessarily limited to, tertiary amines such as triethanolamine, tributanolamine, trimethylamine, triethylamine, tri-n-propylamine, triisopropylamine, tri-n-butylamine, tri-tert-butylamine, tri-n-octylamine, triisopropanolamine, phenyl diethanolamine, stearyl diethanolamine, and diazabicyclooctane; and aromatic amines such as pyridine and 4-dimethylaminopyridine. Additional examples of the amines include primary amines such as benzylamine and n-butylamine; and secondary amines such as diethylamine and di-n-butylamine. These amines may be used singly or in combination of two or more of them.

The composition for forming a photosensitive resist underlayer film of the present invention includes the basic compound in an amount of, for example, 0% to 5% by mass or 0% to 1% by mass based on the solid content in the composition for forming a photosensitive resist underlayer film. This is because a composition including the basic compound in an amount of more than 1% by mass may reduce sensitivity.

The composition for forming a photosensitive resist underlayer film of the present invention may include a surfactant. The surfactant can further improve coating properties of the composition for forming a photosensitive resist underlayer film with respect to a substrate.

Specific examples of the surfactant include, but are not necessarily limited to, nonionic surfactants including polyoxyethylene alkyl ethers such as polyoxyethylene lauryl ether, polyoxyethylene stearyl ether, polyoxyethylene cetyl ether, and polyoxyethylene oleyl ether; polyoxyethylene alkylallyl ethers such as polyoxyethylene octylphenol ether and polyoxyethylene nonylphenol ether; polyoxyethylene-polyoxypropylene block copolymers; sorbitan aliphatic acid esters such as sorbitan monolaurate, sorbitan monopalmitate, sorbitan monostearate, sorbitan monooleate, sorbitan trioleate, and sorbitan tristearate; and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorochemical surfactants including EFTOP EF301, EFTOP EF303, and EFTOP EF352 (manufactured by Mitsubishi Materials Electronic Chemicals Co., Ltd. (formerly Jemco Co.)), MEGAFAC F171, MEGAFAC F173, MEGAFAC F176, MEGAFAC F189, and MEGAFAC R03 (manufactured by DIC Corporation (formerly Dainippon Ink and Chemicals, Inc.)), Fluorad FC430 and Fluorad FC431 (manufactured by Sumitomo 3M Limited), Asahiguard AG710, Surflon 5382, Surflon SC101, Surflon SC102, Surflon SC103, Surflon SC104, Surflon SC105, and Surflon SC106 (manufactured by ASAHI GLASS CO., LTD.); and organosiloxane polymer KP-341 (manufactured by Shin-Etsu Chemical Co., Ltd.). These surfactants may be used singly or in combination of two or more of them.

The composition for forming a photosensitive resist underlayer film of the present invention include the surfactant commonly in an amount of 3% by mass or less, preferably 1% by mass or less, and more preferably 0.5% by mass or less, based on the solid content in the composition for forming a photosensitive resist underlayer film.

The composition for forming a photosensitive resist underlayer film of the present invention may further include a rheology control agent, an adhesion assistant, and the like as necessary.

The composition for forming a photosensitive resist underlayer film of the present invention can be prepared by dissolving each component in an appropriate solvent and can be obtained in a homogeneous solution state.

Examples of the solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol propyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, methyl 3-ethoxypropionate, ethyl 3-ethoxypropionate, methyl pyruvate, ethyl pyruvate, ethyl acetate, butyl acetate, ethyl lactate, butyl lactate, N,N-dimethylformamide, N,N-dimethylacetamide, and N-methylpyrrolidone. These solvents may be used singly or in combination of two or more of them. A high-boiling solvent such as propylene glycol monobutyl ether and propylene glycol monobutyl ether acetate may further be used as a mixture.

The composition (solution) for forming a photosensitive resist underlayer film prepared in this manner is preferably filtered using, for example, a filter typically having a pore size of about 0.2 μm or 0.1 μm before use. The composition for forming a photosensitive resist underlayer film prepared in this manner has excellent storage stability at room temperature for a long time.

Hereinafter, the use of the composition for forming a photosensitive resist underlayer film of the present invention will be described.

On a substrate {for example, a semiconductor substrate such as a silicon coated with a silicon oxide film, a semiconductor substrate such as a silicon coated with a silicon nitride film or a silicon nitride-oxide film, a silicon nitride substrate, a quartz substrate, a glass substrate (including a non-alkali glass, a low-alkali glass, and a crystallized glass), and a glass substrate with an ITO film}, the composition for forming a photosensitive resist underlayer film of the present invention is applied by an appropriate coating means such as a spinner and a coater, followed by baking using a heating means such as a hot plate to form a resist underlayer film.

The baking conditions are appropriately selected from a baking temperature of 80° C. to 250° C. and a baking time of 0.3 minutes to 60 minutes, and are preferably a baking temperature of 130° C. to 250° C. and a baking time of 0.5 minutes to 5 minutes. A baking temperature lower than the above range may lead to an insufficient cross-linked structure in the resist underlayer film and may cause intermixing of the resist underlayer film with a photoresist. An excessively high baking temperature may lead to the cleavage of a cross-linked structure in the resist underlayer film and may cause intermixing of the resist underlayer film with a photoresist.

The resist underlayer film formed from the composition for forming a photosensitive resist underlayer film of the present invention commonly has a film thickness of 0.001 μm to 3.0 μm, preferably 0.01 μm to 1.0 μm, and more preferably 0.03 μm to 0.5 μm.

The resist underlayer film formed from the composition for forming a photosensitive resist underlayer film of the present invention becomes a rigid film having a cross-linked structure by, in the baking condition at the time of formation, reacting a phenolic hydroxy group in a polymer having the structural unit of Formula (1) or a polymer having the structural units of Formula (1) and Formula (2) with the compound having at least two vinyl ether groups to form cross-linkages. Accordingly, the resist underlayer film obtains a low solubility in an organic solvent that is commonly used in a photoresist solution to be applied onto the resist underlayer film, such as ethylene glycol monomethyl ether, ethylene cellosolve acetate, diethylene glycol monoethyl ether, propylene glycol, propylene glycol monomethyl ether, propylene glycol monomethyl ether acetate, propylene glycol propyl ether acetate, toluene, methyl ethyl ketone, cyclohexanone, γ-butyrolactone, ethyl 2-hydroxypropionate, ethyl 2-hydroxy-2-methylpropionate, ethyl ethoxyacetate, methyl pyruvate, ethyl lactate, and butyl lactate.

Next, on the resist underlayer film, a photoresist layer is formed. The formation of the photoresist layer can be performed by a common method, that is, by applying a photoresist solution onto the resist underlayer film followed by baking.

The photoresist formed on the resist underlayer film obtained from the composition for forming a photosensitive resist underlayer film of the present invention is not particularly limited as long as the photoresist is exposed to exposure light to function as a positive photoresist. Examples of the photoresist include a positive photoresist composed of a novolac resin and 1,2-naphthoquinone diazide sulfonic acid ester, a chemically amplified photoresist composed of a photo-acid generator and a binder having a group that is degraded by an acid to increase an alkali dissolution rate, a chemically amplified photoresist composed of a photo-acid generator, an alkali soluble binder, and a low molecular compound that is degraded by an acid to increase the alkali dissolution rate of a photoresist, and a chemically amplified photoresist composed of a binder having a group that is degraded by an acid to increased an alkali dissolution rate, a low molecular compound that is degraded by an acid to increase the alkali dissolution rate of a photoresist, and a photo-acid generator. Specific examples of the photoresist include trade name: APEX-X (manufactured by Rohm and Haas Electronic Materials (formerly Shipley)), trade name: PAR710 (manufactured by Sumitomo Chemical Co., Ltd.), and trade name: SEPR430 (manufactured by Shin-Etsu Chemical Co., Ltd.).

In the present invention, in the method for forming a photoresist pattern that is used in the production of a semiconductor device, the exposure is performed through a predetermined mask. The exposure may employ KrF excimer laser (wavelength 248 nm), ArF excimer laser (wavelength 193 nm), or the like. After the exposure, post exposure bake is performed as necessary. The conditions for the post exposure bake are appropriately selected from a heating temperature of 80° C. to 150° C. and a heating time of 0.3 minutes to 60 minutes.

A semiconductor substrate coated with the resist underlayer film and the photoresist layer is exposed using a photomask followed by development to produce a semiconductor device. The resist underlayer film formed from the composition for forming a photosensitive resist underlayer film of the present invention is affected by an acid generated at the time of exposure from a photo-acid generator contained in the resist underlayer film to be soluble in an alkaline developer used for the development of a photoresist. Accordingly, after the exposure, the development of both the resist underlayer film and the photoresist layer at the same time with an alkaline developer removes exposed areas in the resist underlayer film and the photoresist layer because the areas are soluble in an alkali.

Examples of the alkaline developer include alkaline aqueous solutions including an aqueous solution of an alkali metal hydroxide such as potassium hydroxide and sodium hydroxide; an aqueous solution of a quaternary ammonium hydroxide such as tetramethylammonium hydroxide, tetraethylammonium hydroxide, and choline; and an aqueous solution of an amine such as ethanolamine, propylamine, and ethylenediamine. Such a developer may further include a surfactant and the like.

The development conditions are appropriately selected from a development temperature of 5° C. to 50° C. and a development time of 10 seconds to 300 seconds. The resist underlayer film formed from the composition for forming a photosensitive resist underlayer film of the present invention can be easily developed at room temperature using an aqueous solution of 2.38% by mass tetramethylammonium hydroxide that is generally used for the development of a photoresist.

The resist underlayer film formed from the composition for forming a photosensitive resist underlayer film of the present invention can also be used, for example, as a layer for suppressing interaction between a substrate and a photoresist, a layer having a function of suppressing adverse effect of a material used for a photoresist or a substance generated at the time of exposure to a photoresist, on a semiconductor substrate, a layer having a function of suppressing diffusion of a substance generated from a semiconductor substrate at the time of heating, into an upper photoresist layer, and a barrier layer for reducing a poisoning effect of a photoresist due to a dielectric layer.

### EXAMPLES

Hereinafter, the present invention will be specifically described with reference to examples. However, the present invention is not limited to the description in the examples below.

[Determination of Weight Average Molecular Weight of Polymer Obtained in Synthesis Examples Below]

Apparatus: TOSOH HLC-8220GPC system
Column: Shodex [registered trademark] KF-803 L, KF-802, and KF-801
Column temperature: 40° C.
Eluant: tetrahydrofuran
Flow rate: 1 mL/min

### Detector: RI

### Synthesis of Polymer

### Synthesis Example 1

In 37.1 g of tetrahydrofuran, 15.0 g of 4-hydroxyphenyl methacrylate (Showa Highpolymer Co., Ltd.) and 0.9 g of dimethyl 2,2′-azobis(isobutyrate) (Wako Pure Chemical Industries, Ltd.) were dissolved, and the solution was added dropwise into 26.5 g of heated and refluxed tetrahydrofuran in a nitrogen atmosphere. After the completion of the dropwise addition, the whole was reacted for 18 hours while maintaining heating and reflux. Then, the reaction mixed solution was poured into hexane for precipitating a polymer. Next, the polymer was dried under reduced pressure to afford 14.1 g of a polymer of Formula (13). GPC revealed a weight average molecular weight of 24,700 in terms of polystyrene.

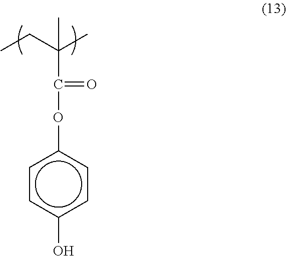

### Synthesis Example 2

In 32.6 g of tetrahydrofuran, 5.5 g of 4-hydroxyphenyl methacrylate (Showa Highpolymer Co., Ltd.), 7.7 g of ethyladamantyl methacrylate (Osaka Organic Chemical Industry Ltd.), and 0.79 g of dimethyl 2,2′-azobis(isobutyrate) (Wako Pure Chemical Industries, Ltd.) were dissolved, and the solution was added dropwise into 23.3 g of propylene glycol monomethyl ether heated at 70° C. in a nitrogen atmosphere. After the completion of the dropwise addition, the whole was reacted for 14 hours while maintaining the temperature at 70° C. Then, the reaction mixed solution was poured into hexane for precipitating a polymer. Next, the polymer was dried under reduced pressure to afford 10.8 g of a polymer of Formula (14). GPC revealed a weight average molecular weight of 10,150 in terms of polystyrene.

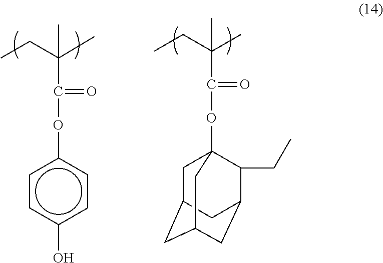

### Synthesis Example 3

In 28.8 g of tetrahydrofuran, 5.5 g of 4-hydroxyphenyl methacrylate (Showa Highpolymer Co., Ltd.), 6.0 g of ethylcyclohexyl methacrylate (Daicel Chemical Industries, Ltd.), and 0.79 g of dimethyl 2,2′-azobis(isobutyrate) (Wako Pure Chemical Industries, Ltd.) were dissolved, and the solution was added dropwise into 20.6 g of heated and refluxed tetrahydrofuran over 6 hours in a nitrogen atmosphere. After the completion of the dropwise addition, the whole was reacted for 16 hours while maintaining heating and reflux. Then, the reaction mixed solution was poured into hexane for precipitating a polymer. Next, the polymer was dried under reduced pressure to afford 9.5 g of a polymer of Formula (15). GPC revealed a weight average molecular weight of 14,600 in terms of polystyrene.

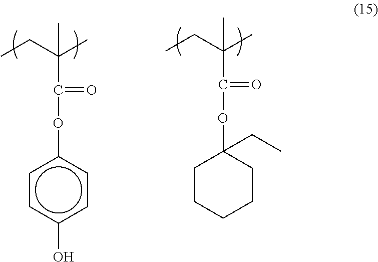

### Synthesis Example 4

In 33.6 g of tetrahydrofuran, 5.5 g of 4-hydroxyphenyl methacrylate (Showa Highpolymer Co., Ltd.), 8.1 g of isopropyladamantyl methacrylate (Daicel Chemical Industries, Ltd.), and 0.79 g of dimethyl 2,2′-azobis(isobutyrate) (Wako Pure Chemical Industries, Ltd.) were dissolved, and the solution was added dropwise into 24.0 g of heated and refluxed tetrahydrofuran over 7 hours in a nitrogen atmosphere. After the completion of the dropwise addition, the whole was reacted for 14 hours while maintaining heating and reflux. Then, the reaction mixed solution was poured into hexane for precipitating a polymer. Next, the polymer was dried under reduced pressure to afford 13.7 g of a polymer of Formula (16). GPC revealed a weight average molecular weight of 16,900 in terms of polystyrene.

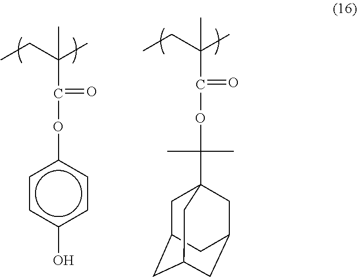

### Synthesis Example 5

In 34.6 g of tetrahydrofuran, 5.5 g of 4-acetoxystyrene (Tosoh Organic Chemical Co., Ltd.), 8.4 g of ethyladamantyl methacrylate (Osaka Organic Chemical Industry Ltd.), and 0.87 g of dimethyl 2,2′-azobis(isobutyrate) (Wako Pure Chemical Industries, Ltd.) were dissolved, and the solution was added dropwise into 24.7 g of propylene glycol monomethyl ether heated at 70° C. in a nitrogen atmosphere. After the completion of the dropwise addition, the whole was reacted for 14 hours while maintaining the temperature at 70° C. Then, the reaction mixed solution was poured into hexane for precipitating a polymer. Next, the polymer was dried under reduced pressure to afford 12.4 g of a polymer of Formula (17).

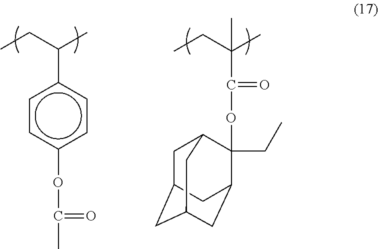

Next, 10 g of the obtained polymer and 3 g of triethylamine were dissolved in 3 g of water, 30 g of methanol, and 30 g of tetrahydrofuran, and the solution was heated and refluxed for 14 hours. Then, the solution was allowed to reach room temperature, and was concentrated. Then, the residue was redissolved in 30 g of acetone, and 3 g of acetic acid was added. Next, the solution was stirred at room temperature for 30 minutes, and the solution was poured into water to afford 9.9 g of a polymer of Formula (18). GPC revealed a weight average molecular weight of 5,900 in terms of polystyrene.

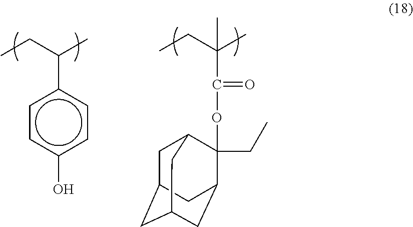

### Preparation of Composition (Solution) for Forming Photosensitive Resist Underlayer Film

### Example 1

With 0.3 g of the polymer obtained in Synthesis Example 1, 0.12 g of 1,3,5-tris(4-vinyloxybutyl)trimellitate of Formula (19), 0.005 g of triphenylsulfonium perfluorobutylsulfonate, and 0.0002 g of triethanolamine were mixed, and the mixture was dissolved in 20.82 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a photosensitive resist underlayer film.

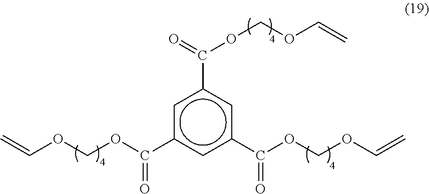

### Example 2

With 0.3 g of the polymer obtained in Synthesis Example 2, 0.12 g of 1,3,5-tris(4-vinyloxybutyl)trimellitate of Formula (19), 0.005 g of triphenylsulfonium perfluorobutylsulfonate, and 0.0008 g of triethanolamine were mixed, and the mixture was dissolved in 20.85 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a photosensitive resist underlayer film.

### Example 3

With 0.3 g of the polymer obtained in Synthesis Example 3, 0.12 g of 1,3,5-tris(4-vinyloxybutyl)trimellitate of Formula (19), 0.005 g of triphenylsulfonium perfluorobutylsulfonate, and 0.0008 g of triethanolamine were mixed, and the mixture was dissolved in 20.85 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a photosensitive resist underlayer film.

### Example 4

With 0.3 g of the polymer obtained in Synthesis Example 4, 0.12 g of 1,3,5-tris(4-vinyloxybutyl)trimellitate of Formula (19), 0.005 g of triphenylsulfonium perfluorobutylsulfonate, and 0.0002 g of triethanolamine were mixed, and the mixture was dissolved in 20.82 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a photosensitive resist underlayer film.

### Example 5

With 0.3 g of the polymer obtained in Synthesis Example 1, 0.12 g of 1,3,5-tris(4-vinyloxybutyl)trimellitate of Formula (19) and 0.005 g of triphenylsulfonium perfluorobutylsulfonate were mixed, and the mixture was dissolved in 20.8 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a resist underlayer film.

### Comparative Example 1

With 0.3 g of poly(4-vinylphenol) (weight average molecular weight Mw 8,000) (Nippon Soda Co., Ltd.), 0.12 g of 1,3,5-tris(4-vinyloxybutyl)trimellitate of Formula (19), 0.005 g of triphenylsulfonium perfluorobutylsulfonate, and 0.0001 g of triethanolamine were mixed, and the mixture was dissolved in 21.93 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a photosensitive resist underlayer film.

### Comparative Example 2

With 0.35 g of the polymer obtained in Synthesis Example 5, 0.14 g of 1,3,5-tris(4-vinyloxybutyl)trimellitate of Formula (19), 0.005 g of triphenylsulfonium perfluorobutylsulfonate, and 0.0001 g of triethanolamine were mixed, and the mixture was dissolved in 25.30 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a photosensitive resist underlayer film.

### Comparative Example 3

With 0.3 g of the polymer obtained in Synthesis Example 1, 0.12 g of 1,3,5-tris(4-vinyloxybutyl)trimellitate of Formula (19) was mixed, and the mixture was dissolved in 20.58 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a resist underlayer film.

### Comparative Example 4

With 0.3 g of the polymer obtained in Synthesis Example 1, 0.12 g of 1,3,5-tris(4-vinyloxybutyl)trimellitate of Formula (19) and 0.0002 g of triethanolamine were mixed, and the mixture was dissolved in 20.8 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a resist underlayer film.

### Comparative Example 5

With 0.3 g of poly(4-vinylphenol) (weight average molecular weight Mw=8,000) (Nippon Soda Co., Ltd.), 0.12 g of 1,3,5-tris(4-vinyloxybutyl)trimellitate of Formula (19) and 0.005 g of triphenylsulfonium perfluorobutylsulfonate were mixed, and the mixture was dissolved in 21.93 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a resist underlayer film.

### Comparative Example 6

With 0.3 g of poly(4-vinylphenol) (weight average molecular weight Mw=8,000) (Nippon Soda Co., Ltd.), 0.12 g of 1,3,5-tris(4-vinyloxybutyl)trimellitate of Formula (19) and 0.0001 g of triethanolamine were mixed, and the mixture was dissolved in 21.69 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a resist underlayer film.

### Comparative Example 7

With 0.3 g of poly(4-vinylphenol) (weight average molecular weight Mw=8,000) (Nippon Soda Co., Ltd.), 0.12 g of 1,3,5-tris(4-vinyloxybutyl)trimellitate of Formula (19) was mixed, and the mixture was dissolved in 21.69 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a photosensitive resist underlayer film.

### Comparative Example 8

With 0.35 g of the polymer obtained in Synthesis Example 5, 0.14 g of 1,3,5-tris(4-vinyloxybutyl)trimellitate of Formula (19) was mixed, and the mixture was dissolved in 25.30 g of propylene glycol monomethyl ether to make a solution. Then, the solution was filtered using a polyethylene microfilter having a pore size of 0.10 μm and further filtered using a polyethylene microfilter having a pore size of 0.05 μm to prepare a composition (solution) for forming a photosensitive resist underlayer film.

[Elution Test into Photoresist Solvent]

Each composition (solution) for forming a photosensitive resist underlayer film prepared in Examples 1 to 5 and Comparative Examples 1 and 3 to 7 was applied onto a semiconductor substrate (silicon wafer) with a spinner. Then, the substrate was baked using a hot plate at 190° C. for 1 minute to form a resist underlayer film (a film thickness of 0.05 μm). The obtained resist underlayer film was immersed in a solvent used for a photoresist, for example, in propylene glycol monomethyl ether/propylene glycol monomethyl ether acetate=7/3, and it was ascertained that each resist underlayer film had poor solubility in the solvent. The results of the solvent resistance test of Examples 1 to 4 are listed in Table 1.

TABLE 1

| | Polymer | Residual film ratio (%)*¹ |
|---|---|---|
| Example 1 | P-PQMA | 100.0 |
| Example 2 | PQMA/EAMA | 99.0 |
| Example 3 | PQMA/ECMA | 98.6 |
| Example 4 | PQMA/IAM | 99.5 |

*¹A composition showing a residual film ratio of 98% or more is evaluated to have good solvent resistance.

Meanwhile, each composition (solution) for forming a photosensitive resist underlayer film prepared in Comparative Examples 2 and 8 was applied onto a semiconductor substrate (silicon wafer) with a spinner, and then the substrate was baked using a hot plate at 200° C. for 1 minute to form a resist underlayer film (a film thickness of 0.05 μm). The obtained resist underlayer film had poor solubility in a solvent used for a photoresist, for example, in propylene glycol monomethyl ether/propylene glycol monomethyl ether acetate=7/3.

[Evaluation of Pattern Shape]

Each composition (solution) for forming a photosensitive resist underlayer film prepared in Examples 1 to 5 and Comparative Examples 1 and 3 to 7 was applied onto a semiconductor substrate (silicon wafer) using a spinner, and then the substrate was baked using a hot plate at 190° C. for 1 minute to form a resist underlayer film (a film thickness of 0.05 μm). Onto the obtained resist underlayer film, a commercially available photoresist solution (manufactured by JSR Corporation, trade name: V146G) was applied using a spinner, and the substrate was heated using a hot plate at 110° C. for 60 seconds to form a photoresist film (a film thickness of 0.28 μm). Then, the substrate was exposed using a scanner S-205C (wavelength 248 nm, NA: 0.73, σ: 0.85 (CONVENTIONAL)) manufactured by Nikon Corporation through a mask designed so that the photoresist pattern would have a line width of 0.20 μm and a line spacing of 0.20 μm after the development. Next, the substrate was subjected to post exposure bake using a hot plate at 110° C. for 60 seconds. After cooling, the substrate was developed using 0.26N aqueous tetramethylammonium hydroxide solution as a developer.

Meanwhile, each composition (solution) for forming a photosensitive resist underlayer film prepared in Comparative Examples 2 and 8 was applied onto a semiconductor substrate (silicon wafer) using a spinner, and then the substrate was baked using a hot plate at 200° C. for 1 minute to form a resist underlayer film (a film thickness of 0.05 μm). Onto the obtained resist underlayer film, a commercially available photoresist solution (manufactured by JSR Corporation, trade name: V146G) was applied using a spinner, and the substrate was heated using a hot plate at 110° C. for 60 seconds to form a photoresist film (a film thickness of 0.28 μm). Then, the substrate was exposed using a scanner S-205C (wavelength 248 nm, NA: 0.73, σ: 0.85 (CONVENTIONAL)) manufactured by Nikon Corporation through a mask designed so that the photoresist pattern would have a line width of 0.20 μm and a line spacing of 0.20 μm after the development. Next, the substrate was subjected to post exposure bake using a hot plate at 110° C. for 60 seconds. After cooling, the substrate was developed using 0.26N aqueous tetramethylammonium hydroxide solution as a developer.

After the development, each cross section of the obtained photoresist patterns was observed under a scanning electron microscope (SEM).

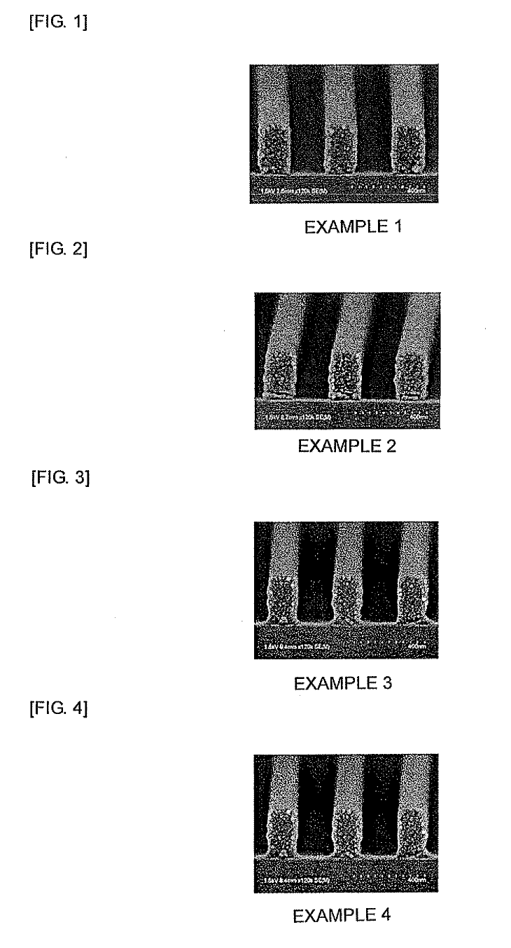

When each composition (solution) for forming a photosensitive resist underlayer film prepared in Examples 1 to 5 was used, the obtained photoresist pattern had a shape in which the resist underlayer film was well resolved as shown in FIG. 1 to FIG. 5 and no residue was observed. In contrast, when the composition (solution) for forming a photosensitive resist underlayer film prepared in Comparative Example 1 was used, the resist underlayer film was not developed and a residue of the resist underlayer film remained between lines of the photoresist pattern (see FIG. 6). When the composition (solution) for forming a photosensitive resist underlayer film prepared in Comparative Example 2 was used, the resist underlayer film was excessively developed and the photoresist pattern collapsed.

Next, using p-PQMA (poly(4-hydroxyphenyl methacrylate)) and p-HSt (poly(4-vinylphenol)) as polymers included in the composition for forming a photosensitive resist underlayer film of the present invention, effect of each additive included in the composition was studied. Vinylphenol is also called hydroxystyrene.

The polymer used in each Example and each Comparative Example and the additives included in the composition (solution) are listed in Table 2.

TABLE 2

| | | Cross- | Photo- | |
|---|---|---|---|---|
| | | linking | acid | Basic |
| | Polymer | agent | generator | compound |
| Example 1 | p-PQMA | ◯ | ◯ | ◯ |
| Example 2 | PQMA/EAMA | ◯ | ◯ | ◯ |
| Example 3 | PQMA/ECMA | ◯ | ◯ | ◯ |
| Example 4 | PQMA/IAM | ◯ | ◯ | ◯ |
| Example 5 | p-PQMA | ◯ | ◯ | — |
| Comparative | p-HSt | ◯ | ◯ | ◯ |
| Example 1 | | | | |
| Comparative | HSt/EAMA | ◯ | ◯ | ◯ |
| Example 2 | | | | |
| Comparative | p-PQMA | ◯ | — | — |
| Example 3 | | | | |
| Comparative | p-PQMA | ◯ | — | ◯ |
| Example 4 | | | | |
| Comparative | p-HSt | ◯ | ◯ | — |
| Example 5 | | | | |
| Comparative | p-HSt | ◯ | — | ◯ |
| Example 6 | | | | |
| Comparative | p-HSt | ◯ | — | — |
| Example 7 | | | | |
| Comparative | HSt/EAMA | ◯ | — | — |
| Example 8 | | | | |

In the cases of Comparative Examples 3 and 7 where no photo-acid generator and no basic compound (quencher) as a sensitivity adjuster were added, a residue of the resist underlayer film remained after development in Comparative Example 3 (see FIG. 7), while the resist underlayer film had a skirt shape because the shape control of the resist underlayer film was difficult in Comparative Example 7 (see FIG. 11).

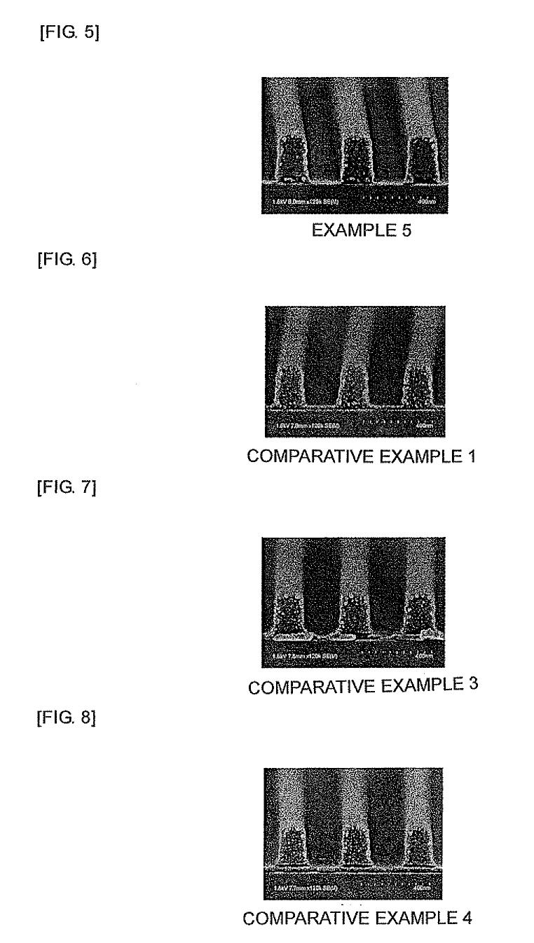

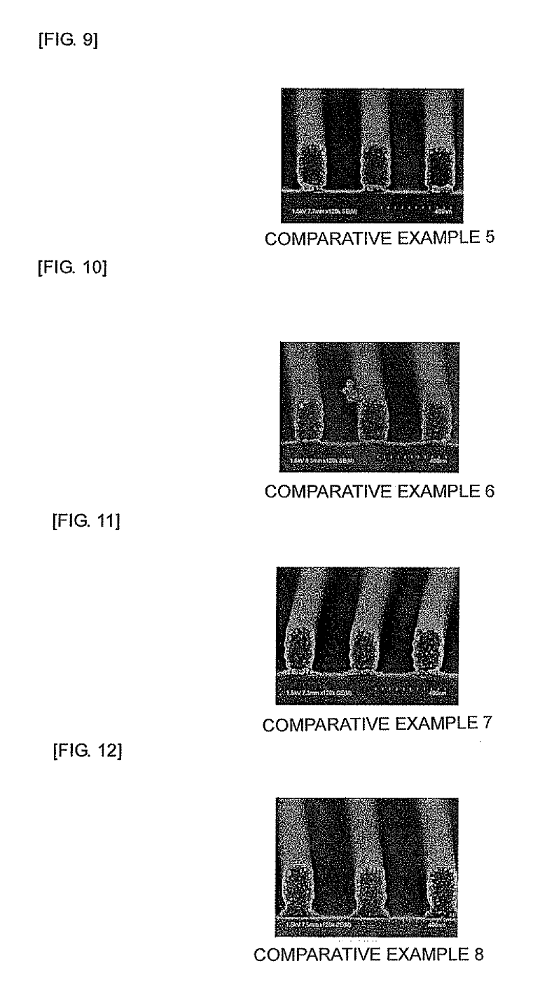

Next, in the cases of Example 5 and Comparative Example 5 where a photo-acid generator was added and no basic compound was added, no residue of the resist underlayer film remained and a fine pattern shape was observed in Example 5 (see FIG. 5), while the resist underlayer film was excessively developed and consequently a part of the resist underlayer film beneath the photoresist pattern was removed to produce an undercut shape in Comparative Example 5 (see FIG. 9).

In Comparative Example 4 and Comparative Example 6 where no photo-acid generator was added and a basic compound was added, the resist underlayer film was not resolved in each case (see FIG. 8 and FIG. 10).

Comparing Example 1 with Comparative Example 1 where a photo-acid generator and a basic compound were added, no residue of the resist underlayer film remained and a fine pattern shape was observed after development in Example 1 (see FIG. 1). In contrast, it was revealed that the resist underlayer film was not resolved in Comparative Example 1 (see FIG. 6).

These results reveal that, comparing with the case where poly(4-vinylphenol) was used as a polymer included in the composition for forming a photosensitive resist underlayer film, the case where poly(4-hydroxyphenyl methacrylate) was included together with a photo-acid generator produced no residue of the resist underlayer film, thereby facilitating the shape control of the resist underlayer film.

1. A composition for forming a photosensitive resist underlayer film comprising:
a polymer having a structural unit of Formula (1);
a compound having at least two vinyl ether groups;
a photo-acid generator; and
a solvent: 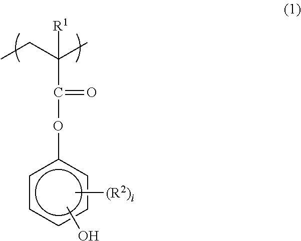
(where R¹ is a hydrogen atom or a methyl group, R² is a C₁₋₄ alkyl group, and i is an integer of 0 to 4).

2. The composition for forming a photosensitive resist underlayer film according to claim 1, wherein the polymer further comprises a structural unit of Formula (2): 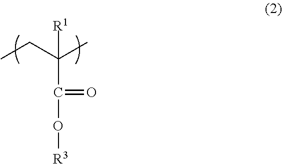
(where R¹ is a hydrogen atom or a methyl group, and R³ is a substituent capable of being deprotected by an acid).

3. The composition for forming a photosensitive resist underlayer film according to claim 2, wherein the substituent R³ capable of being deprotected by an acid is a hydrocarbon group in which the carbon atom bonded to the oxygen atom is a tertiary carbon atom.

4. The composition for forming a photosensitive resist underlayer film according to claim 2, wherein the structural unit of Formula (2) is one type or two or more types selected from structural units of Formula (3) to Formula (9): 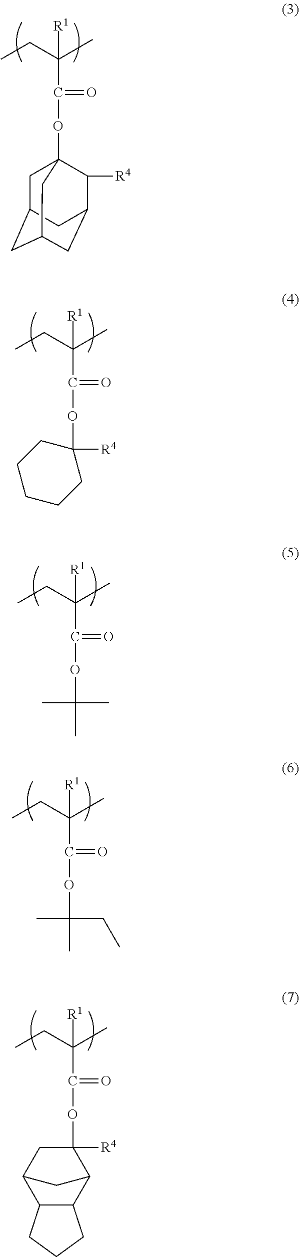 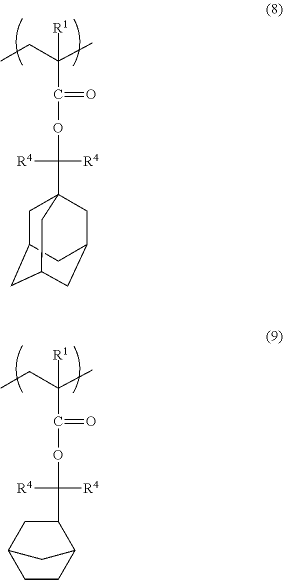
(where R¹ is a hydrogen atom or a methyl group, and R⁴ is a C₁₋₄ alkyl group; and for a plurality of R⁴s in a structural unit, R⁴s may be the same as or different from each other).

5. The composition for forming a photosensitive resist underlayer film according to claim 1, further comprising a basic compound.

6. A method for forming a photoresist pattern used for producing a semiconductor device, the method comprising:
applying the composition for forming a photosensitive resist underlayer film as claimed in claim 1 onto a semiconductor substrate followed by baking to form a resist underlayer film;
forming a photoresist film on the resist underlayer film;
exposing the semiconductor substrate covered with the resist underlayer film and the photoresist layer; and
developing the semiconductor substrate after the exposure.
